(19) United States
(12) Patent Application Publication
(10) Pub. No.: US 2024/0267008 A1
(43) Pub. Date: Aug. 8, 2024

(54) AUDIO AMPLIFIER AND METHOD OF OPERATING THE SAME

(71) Applicant: SAMSUNG ELECTRONICS CO., LTD., SUWON-SI (KR)

(72) Inventors: INHWAN CHO, SUWON-SI (KR); MYUNG-JIN LEE, SUWON-SI (KR)

(21) Appl. No.: 18/525,479

(22) Filed: Nov. 30, 2023

(30) Foreign Application Priority Data
Feb. 6, 2023 (KR) 10-2023-0015775
Apr. 21, 2023 (KR) 10-2023-0052720

(51) Int. Cl. H03F 3/217; H03F 3/45

(52) U.S. Cl. CPC H03F 3/2171; H03F 3/45475; H03F 2200/03; H03F 2200/351; H03F 2203/45424; H03F 2203/45434

(57) ABSTRACT

An audio amplifier includes a loop filter configured to receive a differential input signal pair, a pulse-width modulation (PWM) signal generator configured to generate PWM signals, corresponding to the differential input signal pair, based on signals received from the loop filter, a driver configured to generate an output signal pair based on the PWM signals, a feedback circuit configured to feed back the output signal pair to the loop filter, and a common mode compensation circuit configured to compensate for a fluctuation in a common mode voltage of the fed-back output signal pair. The common mode compensation circuit generates a compensation voltage for each of a plurality of levels of the common mode voltage, and provides the generated compensation voltage to the loop filter.

### CROSS-REFERENCE TO RELATED APPLICATION(S)

This application claims priority under 35 U.S.C. § 119 to Korean Patent Application No. 10-2023-0015775 filed on Feb. 6, 2023, and Korean Patent Application No. 10-2023-0052720 filed on Apr. 21, 2023, the disclosures of which are incorporated by reference herein in their entireties.

### TECHNICAL FIELD

Embodiments of the present disclosure relate to an audio amplifier and a method of operating the same.

### Discussion of Related Art

An audio amplifier is a circuit that amplifies an audio signal input from a source device and outputs the amplified audio signal to a speaker. Audio amplifiers may be classified into a class A amplifier, a class B amplifier, a class AB amplifier, a class D amplifier, a class G amplifier, a class H amplifier, or the like, depending on the type of an output terminal.

A class D amplifier, which has been most widely used as an audio amplifier, is also referred to as a digital amplifier, a switching amplifier, or a pulse-width modulation (PWM) amplifier. Since a class D amplifier operates by fully turning on or off a metal-oxide-silicon (MOS) switch through PWM control, there is almost no power loss, resulting in high-efficiency amplification.

### SUMMARY

Example embodiments provide an audio amplifier capable of compensating for a fluctuation in common source voltage under various power supply conditions, and a method of operating the same.

According to an example embodiment, an audio amplifier includes a loop filter configured to receive a differential input signal pair, a pulse-width modulation (PWM) signal generator configured to generate PWM signals, corresponding to the differential input signal pair, based on signals received from the loop filter, a driver configured to generate an output signal pair based on the PWM signals, a feedback circuit configured to feed back the output signal pair to the loop filter, and a common mode compensation circuit configured to compensate for a fluctuation in common mode voltage of the fed-back output signal pair. The common mode compensation circuit generates a compensation voltage for each of a plurality of levels of the common mode voltage, and provides the generated compensation voltage to the loop filter.

The PWM signal generator may be driven by a power supply voltage, the driver may be driven by a driving voltage higher than or equal to the power supply voltage, and the common mode compensation circuit may generate the compensation voltage based on the PWM signals.

The PWM signal generator may include a first comparator configured to generate a first PWM signal by comparing a triangle wave with a first output of the loop filter, and a second comparator configured to generate a second PWM signal by comparing the triangle wave with a second output of the loop filter. The common mode compensation circuit may generate the compensation voltage based on the first PWM signal and the second PWM signal.

The common mode compensation circuit may include a control node connected to a first input terminal and a second input terminal of the loop filter. The common mode compensation circuit may be configured to apply a ground voltage to the control node when both a first output signal and a second output signal, included in the output signal pair, are at a high level, apply the driving voltage to the control node when both the first and second output signals are at a low level, and apply a mean voltage of the driving voltage and the ground voltage to the control node when one of the first and second output signals is at a high level and the other one of the first and second output signals is at a low level.

The first and second input terminals may be connected to an input terminal pair of a first amplifier included in the loop filter. The feedback circuit may include a first feedback resistor configured to feed back the first output signal to the first input terminal of the loop filter, and a second feedback resistor configured to feed back the second output signal to the second input terminal of the loop filter. The common mode compensation circuit may include a first compensation resistor connected between the control node and the first input terminal of the loop filter, and a second compensation resistor connected between the control node and the second input terminal of the loop filter.

A positive input signal, included in the differential input signal pair, may be applied to the first input terminal of the loop filter through a first input resistor. A negative input signal, included in the differential input signal pair, may be applied to the second input terminal of the loop filter through a second input resistor. The first output signal may be a negative output signal included in the output signal pair, and the second output signal may be a positive signal included in the output signal pair.

The common mode compensation circuit may include a first switch having one end connected to the ground voltage and another end connected to the control node, a second switch having one end connected to the driving voltage and another end connected to the control node, a third switch having one end connected to the ground voltage and another end connected to the control node through a first intermediate resistor, and a fourth switch having one end connected to the driving voltage and another end connected to the control node through a second intermediate resistor.

The common mode compensation circuit may include a first logic gate configured to generate a first control signal that controls turn-on and turn-off operations of the first switch, a second logic gate configured to generate a second control signal that controls turn-on and turn-off operations of the second switch, and a third logic gate configured to generate a third control signal that controls turn-on and turn-off operations of the third and fourth switches.

The common mode compensation circuit may include a first inverter configured to generate a first inverted PWM signal by inverting the first PWM signal, and a second inverter configured to generate a second inverted PWM signal by inverting the second PWM signal. The first logic gate may be a NOR gate configured to generate the first control signal based on the first and second inverted PWM signals and to output the generated first control signal to a gate terminal of the first switch. The second logic gate may be an AND gate configured to generate the second control signal based on the first and second inverted PWM signals and to output the generated second control signal to a gate terminal of the second switch. The third logic gate may be an XOR gate configured to generate the third control signal based on the first and second inverted PWM signals and to output the generated third control signal to a gate terminal of the third switch and a gate terminal of the fourth switch.

Each of the first to fourth switches is an n-type metal oxide (NMOS) switch. The common mode compensation circuit may include a first bootstrap circuit configured to bootstrap the second control signal applied to the gate terminal of the second switch, and a second bootstrap circuit configured to bootstrap the third control signal applied to the gate terminal of the fourth switch.

Each of the first and third switches may be an n-type metal oxide semiconductor (NMOS) switch, and each of the second and fourth switches may be a p-type metal oxide semiconductor (PMOS) switch. The common mode compensation circuit may include a third inverter configured to invert the second control signal applied to the gate terminal of the second switch, and a fourth inverter configured to invert the third control signal applied to the gate terminal of the fourth switch.

A value of a DC level of the differential input signal pair and a value of the mean voltage may be different.

The first feedback resistor, the second feedback resistor, the first compensation resistor, and the second compensation resistor may have a same resistance value.

Each of the first to fourth switches may be a lateral double-diffused MOS (LDMOS) switch.

The driver may include a gate driver configured to generate driving signals based on the PWM signals, and a power driver comprising a plurality of switches driven by the driving signal and configured to generate the output signal pair.

Each of the plurality of switches of the power driver and the first to fourth switches may be an NMOS switch.

The plurality of switches of the power driver may include a PMOS switch connected to the driving voltage, and an NMOS switch connected to the ground voltage. Each of the first and third switches may be an NMOS switch, and each of the second and fourth switches may be a PMOS switch.

The audio amplifier may be a class D amplifier with DB modulation.

According to an example embodiment, a method of operating an audio amplifier includes receiving an audio signal through an input terminal of a loop filter of the audio amplifier, generating a pulse-width modulation (PWM) signal corresponding to the audio signal, generating an output signal to be output to a speaker, based on the PWM signal, feeding back the output signal to the loop filter, and compensating for a fluctuation in a common mode voltage of the fed-back output signal. Compensating for the fluctuation may include generating a compensation voltage for each of a plurality of levels of the common mode voltage and providing the generated compensation voltage to the loop filter.

According to an example embodiment, a class D audio amplifier with BD modulation includes a loop filter, a pulse-width modulation (PWM) signal generator, a gate driver, a power driver, a feedback circuit, and a common mode compensation circuit. The common mode compensation circuit may include a control node connected to a first input terminal and a second input terminal of the loop filter. The common mode compensation circuit may be configured to apply a ground voltage to the control node when both a first output signal and a second output signal of the class D audio amplifier are at a high level, apply a driving voltage to the control node when both the first output signal and the second output signal are at a low level, and apply a mean voltage of the driving voltage and the ground voltage to the control node when one of the first and second output signals is at a high level and the other one of the first and second output signals is at a low level.

### BRIEF DESCRIPTION OF THE DRAWINGS

The above and other features of the present disclosure will become more apparent by describing in detail embodiments thereof with reference to the accompanying drawings.

FIG. 1 is a block diagram illustrating a configuration of an audio amplifier according to an example embodiment.

FIG. 2 is a timing diagram illustrating a fluctuation in output common mode voltage.

FIG. 3 is a block diagram of a common mode compensation circuit according to an example embodiment.

FIG. 4 is a diagram illustrating an example of implementing an audio amplifier according to an example embodiment.

FIG. 5 is a table illustrating states of main nodes depending on a state of an output signal pair in the audio amplifier illustrated in FIG. 4.

FIG. 6A is a diagram illustrating a fluctuation in input common mode voltage fed back to an input terminal of a loop filter.

FIG. 6B is a diagram illustrating an operation of eliminating the fluctuation in the input common mode voltage fed back to the input terminal of the loop filter according to an example embodiment.

FIG. 6C is a diagram illustrating an operation of an audio amplifier when a compensation voltage, corresponding to a level of a mean voltage, is not generated.

FIG. 7 is a flowchart illustrating a method of operating an audio amplifier according to an example embodiment.

FIG. 8A is a diagram illustrating an example of implementing a common mode compensation circuit according to an example embodiment.

FIG. 8B is a diagram illustrating an example of implementing a common mode compensation circuit according to an example embodiment.

FIG. 9A is a diagram illustrating a configuration of a driver according to an example embodiment.

FIG. 9B is a diagram illustrating a configuration of a driver according to an example embodiment.

FIG. 10A is a diagram illustrating a waveform of an audio amplifier according to various embodiments.

FIG. 10B is a diagram illustrating a waveform of an audio amplifier according to various embodiments.

FIG. 10C is a diagram illustrating a waveform of an audio amplifier according to various embodiments.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

It will be further understood that when a component is referred to as being ‘on’, ‘connected to’, ‘coupled to’, or ‘adjacent to’ another component, it can be directly on, connected to, coupled to, or adjacent to the other component, or intervening components may also be present. It will also be understood that when a component is referred to as being ‘between’ two components, it can be the only component between the two components, or one or more intervening components may also be present. Other words used to describe the relationships between components should be interpreted in a like fashion.

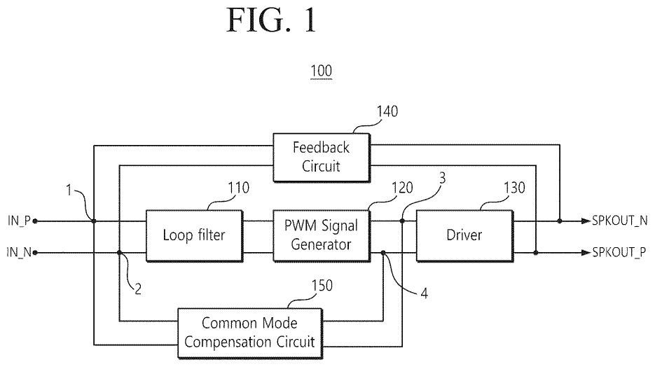

FIG. 1 is a block diagram illustrating a configuration of an audio amplifier according to an example embodiment. Referring to FIG. 1, an audio amplifier 100 may include a loop filter 110 (also referred to as a loop filter circuit), a pulse-width modulation (PWM) signal generator 120 (also referred to as a PWM signal generator circuit), a driver 130 (also referred to as a driver circuit), a feedback circuit 140, and a common mode compensation circuit 150.

The loop filter 110 may receive a differential input signal pair IN_P and IN_N, input to the audio amplifier 100, through input terminals 1 and 2. In this case, the differential input signal pair IN_P and IN_N may be an analog audio signal received from an external device (for example, a source device).

The loop filter 110 may be connected to the PWM signal generator 120. The differential input signal pair, input to the loop filter 110, may be provided to the PWM signal generator 120 after linearity thereof is increased by a loop gain of the loop filter 110.

The PWM signal generator 120 may generate PWM signals, corresponding to the differential input signal pair, based on signals received from the loop filter 110. For example, the PWM signal generator 120 may compare the signals received from the loop filter 110 with a triangle wave having a predefined frequency to generate PWM signals. The generated PWM signals may be provided to the driver 130.

The driver 130 may generate an output signal pair SPKOUT_N and SPKOUT_P based on the PWM signals generated by the PWM signal generator 120. The output signal pair may be output through a speaker.

The output signal pair may be fed back to the loop filter 110 through the feedback circuit 140. For example, the output signal pair may be applied to the input terminals 1 and 2 of the loop filter 110 through the feedback circuit 140.

As described above, the loop filter 110, the PWM signal generator 120, and the feedback circuit 140 may form a loop for amplifying the differentia input signal pair. In this case, the output signal pair is fed back to the input terminals 1 and 2 of the loop filter 110, so that a fluctuation in common mode voltage of the output signal pair may affect performance of the audio amplifier 100.

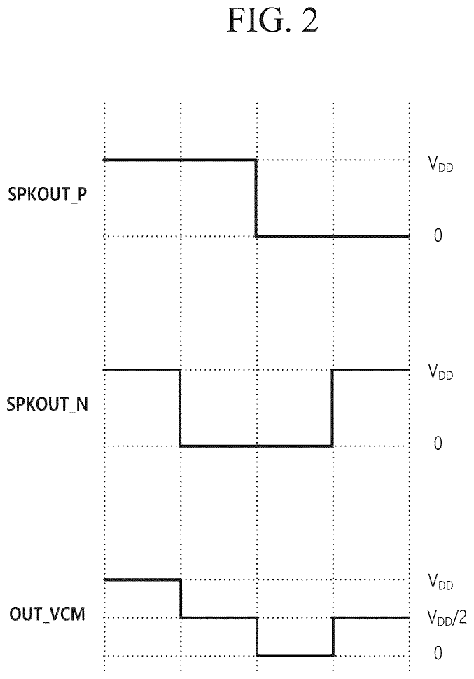

FIG. 2 illustrates an output signal pair SPKOUT_P and SPKOUT_N and a common mode voltage OUT_VCM thereof when the audio amplifier 100 is a class D amplifier with BD modulation. Referring to FIG. 2, when both of the output signals of the output signal pair are at a high level (for example, V_{DD}[V]), the common mode voltage OUT_VCM may become V_{DD}, when both of the output signals of the output signal pair are at a low level (for example, O[V]), the common mode voltage OUT_VCM may become a voltage of “0,” and when one of the output signals of the output signal pair is at a low level and the other output signal is at a high level, the common mode voltage OUT_VCM may become V_{DD}/2. As described above, the output common mode voltage OUT_VCM may not be maintained to be constant at V_{DD}/2 and may fluctuate between three levels V_{DD}[V], V_{DD}/2[V], and O[V].

The output common mode voltage OUT_VCM may be input to the loop filter 110 through the feedback circuit 140 to affect the performance of the audio amplifier 100. In this case, the output common mode voltage OUT_VCM, input to the loop filter 110 through the feedback circuit 140, may be referred to as an input common mode voltage.

For example, as a driving voltage V_{DD} at the output terminal of the audio amplifier 100 is increased, a fluctuation in the output common mode voltage may be increased. When a fluctuation in the output common mode voltage fed back to the loop filter 110 (for example, the input common mode voltage) is outside an input range of an amplifier in the loop filter 110, overall performance of the audio amplifier 100 may be significantly deteriorated.

To address the above issue, the common mode compensation circuit 150 may compensate for the fluctuation in the input common mode voltage. For example, according to an example embodiment, the common mode compensation circuit 150 may generate a compensation voltage for each of a plurality of levels of the common mode voltage of the output signal pair, and may provide the generated compensation voltage to the loop filter 110. Accordingly, the fluctuation in the input common mode voltage may be compensated for.

For example, when the feedback circuit 140 has a resistance value of zero in the above example, a common mode voltage fluctuating between V_{DD}[V], V_{DD}/2[V], and O[V] may be fed back to the input terminals 1 and 2 of the loop filter 110. In this case, the common mode compensation circuit 150 may generate a compensation voltage of 0[V] when both of the output signals of the output signal pair are at a high level, generate a compensation voltage of V_{DD}[V] when both of the output signals of the output signal pair are at a low level, and generate a compensation voltage of V_{DD}/2[V] when one of the output signals of the output signal pair is at a low level and the other output signal is at a high level, and may then provide the generated compensation voltage to the loop filter 110. Accordingly, the common mode voltage at the input terminals 1 and 2 of the loop filter 110 may be maintained to be constant at V_{DD}/2 [V], and the above-described issue caused by the fluctuation in the common mode voltage of the output signal pair may be addressed.

When a compensation voltage is not separately provided for the case in which one of the output signals of the output signal pair is at a low level and the other output signal is at a high level, the fluctuation in the common mode voltage may be incompletely eliminated in some cases. However, in example embodiments, the common mode compensation circuit 150 generates and provides a compensation voltage for each of the plurality of levels of the common mode voltage of the output signal pair, so that the fluctuation in the common mode voltage may be compensated for under various power supply conditions without occurrence of issues, such as the issue described above. This will be described in further detail below.

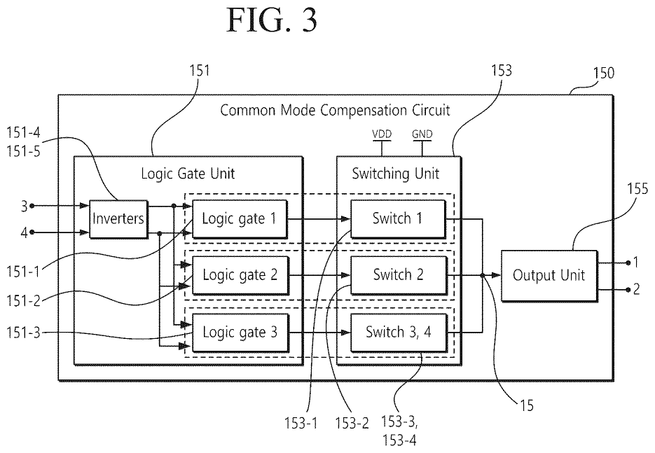

FIG. 3 is a block diagram of a common mode compensation circuit according to an example embodiment.

Referring to FIG. 3, the common mode compensation circuit 150 may include a logic gate unit 151, a switching unit 153, and an output unit 155.

The switching unit 153 may apply a driving voltage V_{DD}, a ground voltage GND, or a mean voltage V_{DD}/2 of the driving voltage V_{DD} and the ground voltage GND to a control node 15 through switching operations of a plurality of switches 153-1, 153-2, 153-3, and 153-4. The voltage, which is applied to the control node 15, may be transmitted to the input terminals 1 and 2 of the loop filter 110 through the output unit 155.

The logic gate unit 151 may generate control signals that control the switching operations of the plurality of switches 153-1, 153-2, 153-3, and 153-4 based on PWM signals output from output terminals 3 and 4 of the PWM signal generator 120.

To this end, the logic gate unit 151 may include a first logic gate 151-1 generating a first control signal that controls turn-on and turn-off operations of the first switch 153-1, a second logic gate 151-2 generating a second control signal that controls turn-on and turn-off operations of the second switch 153-2, and a third logic gate 151-3 generating a third control signal that controls turn-on and turn-off operations of the third and fourth switches 153-3 and 153-4 together.

The PWM signals, received by the common mode compensation circuit 150, may be first input to inverters 151-4 and 151-5, and each of the logic gates 151-1, 151-2 and 151-3 may generate a control signal based on output signals of the inverters 151-4 and 151-5. However, example embodiments are not limited thereto.

According to an example embodiment, the PWM signal generator 120 may be driven by a power supply voltage VBAT, and the driver 130 may be driven by a driving voltage V_{DD} higher than or equal to the power supply voltage VBAT. Since the common mode compensation circuit 150 senses and uses an output of the PWM signal generator 120 using a low voltage, the common mode compensation circuit 150 may be implemented with a significantly small area using a simple logic gate unit 151, as illustrated in FIG. 3.

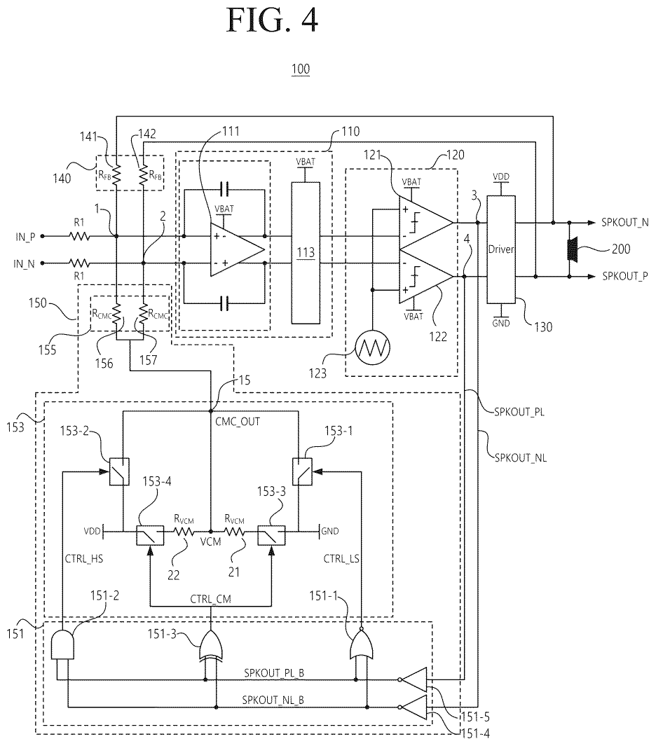

FIG. 4 is a diagram illustrating an example of implementing an audio amplifier according to an example embodiment. Referring to FIG. 4, the audio amplifier 100 may include a loop filter 110, a PWM signal generator 120, a driver 130, a feedback circuit 140, and a common mode compensation circuit 150.

A differential input signal pair IN_P and IN_N may be received at a first input terminal 1 and a second input terminal 2 of the loop filter 110 through an input resistor R1, respectively. The loop filter 110 may output the input differential input signal pair after increasing linearity thereof by a loop gain. The loop filter 110 may include one or more amplifiers depending on an order, and a differential amplifier 111 indicates a first amplifier. The loop filter 110 may further include a high-order loop filter 113 connected to the differential amplifier 111. The first input terminal 1 and the second input terminal 2 of the loop filter 110 may be connected to an input terminal pair of the differential amplifier 111.

The PWM signal generator 120 may generate a PWM signal, corresponding to the differential input signal pair, based on the output signals of the loop filter 110. To this end, the PWM signal generator 120 may include a triangle wave generator 123 that generates a triangle wave of a predefined frequency, a first comparator 121 that compares the triangle wave generated by the triangle wave generator 123 with a first output of the loop filter 110 to generate a first PWM signal, and a second comparator 122 that compares the triangle wave generated by the triangle wave generator 123 with a second output of the loop filter 110 to generate a second PWM signal.

The driver 130 may generate an output signal pair SPKOUT_N and SPKOUT_P based on the PWM signals. For example, the driver 130 may include a gate driver (also referred to as a gate driver circuit) and a power driver (also referred to as a power driver circuit). The gate driver may generate drive signals based on the PWM signals. The power driver may operate a plurality of switches based on driving signals, generated by the gate driver, to generate an output signal pair. The output signal pair may be output through a speaker 200.

The output signal pair may be fed back to the loop filter 110 through the feedback circuit 140. To this end, the feedback circuit 140 may include a first feedback resistor 141 which feeds back a first output signal SPKOUT_N of the output signal pair to the first input terminal 1 of the loop filter 110, and a second feedback resistor 142 which feeds back a second output signal SPKOUT_P of the output signal pair to the second input terminal 2 of the loop filter 110.

The common mode compensation circuit 150 may generate a compensation voltage to compensate for a fluctuation in common mode voltage of the output signal pair SPKOUT_N and SPKOUT_P fed back to the input terminals 1 and 2 of the loop filter 110, and may provide the generated compensation voltage to the loop filter 110.

Still referring to FIG. 4, the common mode compensation circuit 150 may include a control node (CMC_OUT) 15 to which a driving voltage V_{DD}, a ground voltage GND, or a mean voltage of the driving voltage V_{DD} and the ground voltage GND is applied based on a state of the output signal pair.

In addition, the common mode compensation circuit 150 may include a first compensation resistor 156 connected between the control node 15 and the first input terminal 1 of the loop filter 110, and a second compensation resistor 157 connected between the control node 15 and the second input terminals 2 of the loop filter 110. The voltage applied to the control node 15 may be provided to the loop filter 110 through the first and second compensating resistors 151 and 152.

The common mode compensation circuit 150 may include a first switch 153-1 having one end connected to the ground voltage GND and the other end connected to the control node 15, a second switch 153-2 having one end connected to the driving voltage V_{DD} and the other end connected to the control node 15, a third switch 153-3 having one end connected to the ground voltage GND and the other end connected to the control node 15 through a first intermediate resistor 21, and a fourth switch 153-4 having one end connected to the driving voltage V_{DD} and the other end connected to the control node 15 through a second intermediate resistor 22.

Accordingly, a voltage at the control node 15 may become the ground voltage GND when the first switch 153-1 is turned on, become the driving voltage V_{DD} when the second switch 153-2 is turned on, and become the mean voltage of the driving voltage V_{DD} and the ground voltage GND when the third and fourth switches 153-3 and 153-4 are turned on.

The common mode compensation circuit 150 may include a first logic gate 151-1 that generates a first control signal CTRL_LS that controls turn-on and turn-off operations of the first switch 153-1, a second logic gate 151-2 that generates a second control signal CTRL_HS that controls turn-on and turn-off operations of the second switch 153-2, and a third logic gate 151-3 that generates a third control signal CTRL_CM that controls turn-on and turn-off operations of the third and fourth switches 153-3 and 153-4 together. In this case, according to an example embodiment, the first logic gate 151-1 may be a NOR gate, the second logic gate 151-2 may be an AND gate, and the third logic gate 151-3 may be an XOR gate. However, example embodiments are not limited thereto.

As an example, the common mode compensation circuit 150 may include a first inverter 151-4 that generates a first inverted PWM signal SPKOUT_NL_B, and a second inverter 151-5 that generates a second inverted PWM signal SPKOUT_PL_B. The first inverted PWM signal may be an inverted version of the first PWM signal SPKOUT_NL output by the PWM signal generator 120, and the second inverted PWM signal may be an inverted version of the second PWM signal SPKOUT_PL output by the PWM signal generator 120.

Accordingly, the first logic gate 151-1 may generate a first control signal CTRL_LS based on the first and second inverted PWM signals SPKOUT_NL_B and SPKOUT_PL_B, and may output the generated first control signal CTRL_LS to a gate terminal of the first switch 153-1. In addition, the second logic gate 151-2 may generate a second control signal CTRL_HS based on the first and second inverted PWM signals SPKOUT_NL_B and SPKOUT_PL_B, and may output the generated second control signal CTRL_HS to a gate terminal of the second switch 153-2. In addition, the third logic gate 151-3 may generate a third control signal CTRL_CM based on the first and second inverted PWM signals SPKOUT_NL_B and SPKOUT_PL_B, and may output the generated third control signal CTRL_CM to gate terminals of the third and fourth switches 153-3 and 153-4.

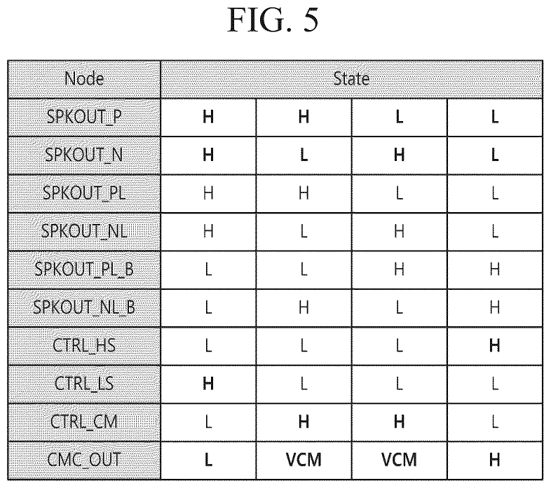

FIG. 5 is a table illustrating states of main nodes depending on a state of an output signal pair in the audio amplifier 100 illustrated in FIG. 4.

Referring to FIGS. 4 and 5 together, the common mode compensation circuit 150 may apply the ground voltage GND to the control node (CMC_OUT) 15 when both the first output signal SPKOUT_N and the second output signal SPKOUT_P are at a high level. Also, the common mode compensation circuit 150 may apply the driving voltage V_{DD} to the control node (CMC_OUT) 15 when both the first output signal SPKOUT_N and the second output signal SPKOUT_P are at a low level. Also, the common mode compensation circuit 150 may apply the mean voltage VCM of the driving voltage V_{DD} and the ground voltage GND to the control node (CMC_OUT) 15 when either one of the first output signal SPKOUT_N and the second output signal SPKOUT_P is at a high level and the other signal is at a low level.

According to an example embodiment, the first feedback resistor 141, the second feedback resistor 142, the first compensation resistor 156, and the second compensation resistor 157 may have the same resistance value. Accordingly, the ground voltage GND may be applied to the control node 15 when the common mode voltage of the output signal pair is a high-level voltage V_{DD}, the driving voltage V_{DD} may be applied to the control node 15 when the common mode voltage of the output signal pair is a low-level voltage GND, and the mean voltage VCM may be applied to the control node 15 when the common mode voltage of the output signal pair is the mean voltage VCM. As a result, a fluctuation in the common mode voltage fed back to the loop filter 110 may be eliminated.

According to an example embodiment, the first to fourth switches 153-1, 153-2, 153-3, and 153-4 may be lateral double-diffused MOS (LDMOS) switches. Since the LDMOS switch has a high breakdown voltage, the fluctuation in the common mode voltage may be eliminated without occurrence of issues even when the high driving voltage V_{DD} is used to configure a high output amplifier.

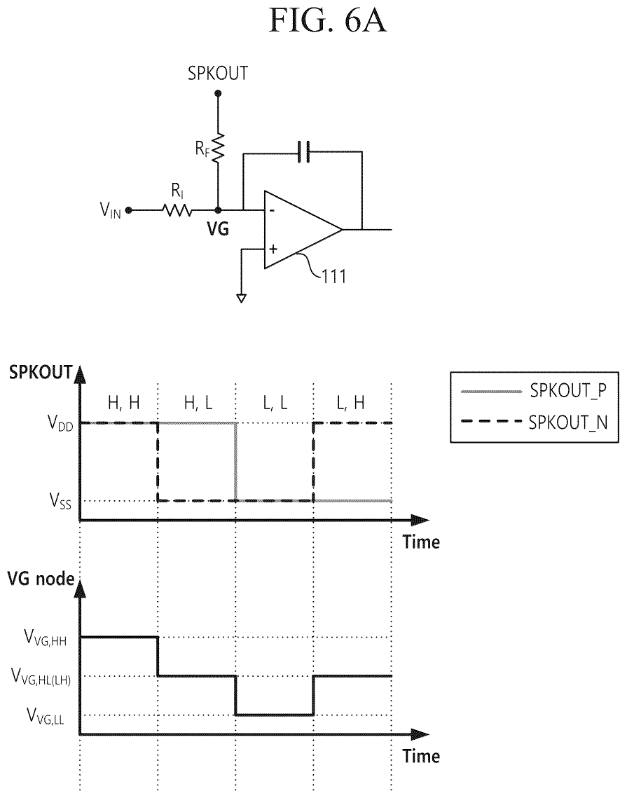

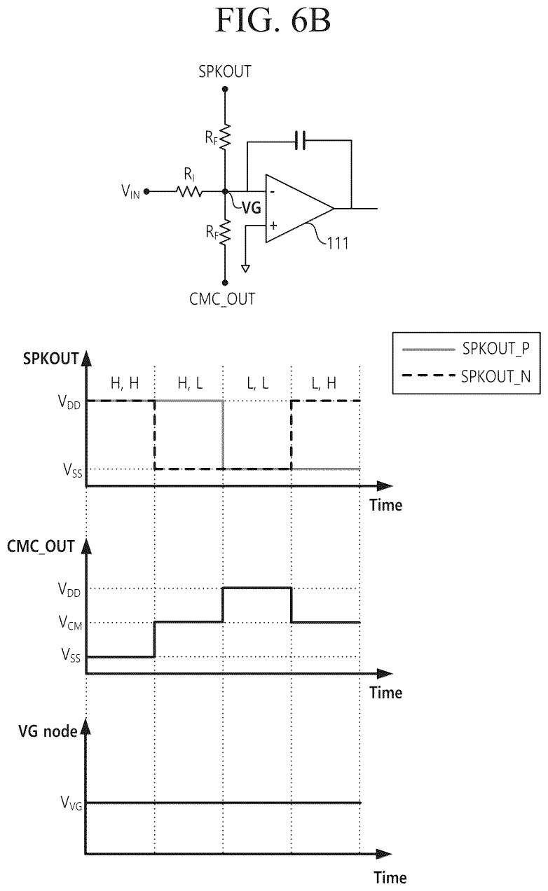

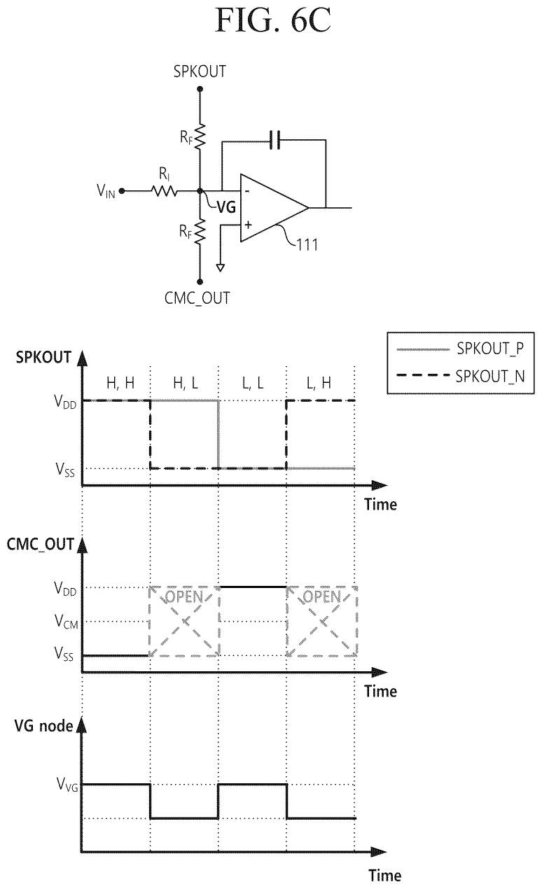

Hereinafter, the operation of the audio amplifier 100 according to example embodiments will be described in more detail with reference to FIGS. 6A to 6C.

FIG. 6A is a diagram illustrating a fluctuation in common mode voltage fed back to an input terminal of a loop filter 110 (for example, an input common mode voltage).

The circuit diagram in an upper portion of FIG. 6A illustrates an input portion of an audio amplifier in a single ended expression when the common mode compensation circuit 150 is absent, and graphs in a lower portion of FIG. 6A illustrate a change in voltage at a virtual ground (VG) node of the first amplifier 111 of the loop filter 110 depending on a state of the output signal SPKOUT. In the graph, V_{SS} represents a ground voltage.

When Kirchhoff's Current Law (KCL) is applied to the VG node, the voltage at the VG node may be calculated as illustrated in Equations 1 to 3 below.

$${V}_{VG , HH} = \frac{{R}_{I}}{{R}_{F} + {R}_{I}} {V}_{DD} + \frac{{R}_{F}}{{R}_{F} + {R}_{I}} {V}_{IN} , \qquad Equation 1$$

where V_{VG,HH} is a voltage at the VG node when both the first output signal SPKOUT_N and the second output signal SPKOUT_P are at a high level, and V_{DD} is a driving voltage used in the driver 130 of the audio amplifier 100, VIN is a DC level of an input signal, R_{I} is a resistance value of an input resistor, and RF is a resistance value of a feedback resistor.

$${V}_{VG , HL ( LH )} = \frac{{R}_{I}}{{R}_{F} + {R}_{I}} \frac{{V}_{DD}}{2} + \frac{{R}_{F}}{{R}_{F} + {R}_{I}} {V}_{IN ,} \qquad Equation 2$$

where V_{VG,HL(LH)} is a voltage at the VG node when one of the first output signal SPKOUT_N and the second output signal SPKOUT_P is at a high level and the other signal is at a low level, V_{DD} is driving voltage used in the driver 130 of the audio amplifier 100, VIN is a DC level of an input signal, R_{I} is a resistance value of an input resistor, and RF is a resistance value of a feedback resistor.

$${V}_{VG , LL} = \frac{{R}_{I}}{{R}_{F} + {R}_{I}} {V}_{IN} , \qquad Equation 3$$

where V_{VG,LL} is a voltage at the VG node when both the first output signal SPKOUT_N and the second output signal SPKOUT_P are at a low level, VIN is a DC level of an input signal, R_{I} is a resistance value of an input resistance, and RF is a resistance value of a feedback resistor.

As can be seen from Equations 1 to 3, when the common mode compensation circuit 150 is absent, the voltage at the virtual ground (VG) node of the amplifier 111 fluctuates depending on the fluctuation in common mode voltage of an output signal pair. In this case, when the fluctuation is outside of an input range of the amplifier 111, overall performance of the audio amplifier 100 may be significantly deteriorated.

FIG. 6B is a diagram illustrating an operation in which a fluctuation in common mode voltage fed back to the input terminal of the loop filter 110 (for example, an input common mode voltage) is eliminated according to an example embodiment. The circuit diagram in an upper portion of FIG. 6B illustrates an input portion of an audio amplifier in a single ended expression when the common mode compensation circuit 150 is present, and graphs in a lower portion of FIG. 6B illustrate voltages at a control node and a virtual ground (VG) node depending on a state of the output signal SPKOUT. In the graph, V_{SS} represents a ground voltage.

As illustrated in FIG. 6B, the voltage at the control node (CMC_OUT) 15 becomes a ground voltage V_{SS} when both the first output signal SPKOUT_N and the second output signal SPKOUT_P are at a high level, becomes a driving voltage V_{DD} when both the first output signal SPKOUT_N and the second output signal SPKOUT_P are at a low level, and becomes a mean voltage VCM of the driving voltage V_{DD} and the ground voltage V_{SS} when one of the first output signal SPKOUT_N and the second output signal SPKOUT_P is at a high level and the other signal is at a low level.

Accordingly, the voltage at the VG node is maintained at a constant value as illustrated in Equation 4 below, regardless of the state of the output signal SPKOUT.

$${V}_{VG} = \frac{{R}_{I}}{{R}_{F} + 2 {R}_{I}} {V}_{DD} + \frac{{R}_{F}}{{R}_{F} + 2 {R}_{I}} {V}_{IN} , \qquad Equation 4$$

where V_{VG} is a voltage at the VG node, V_{DD} is a driving voltage used in the driver 130 of the audio amplifier 100, VIN is a DC level of an input signal, Rr is a resistance value of an input resistor, and RF is a resistance value of the feedback resistor.

FIG. 6C is a diagram illustrating a case in which the common mode compensation circuit 150 is present, but does not generate a compensation voltage corresponding to a level of the mean voltage VCM. A circuit diagram in an upper portion of FIG. 6C illustrates an input portion of an audio amplifier in a single ended expression when the common mode compensation circuit 150 is present, and graphs in a lower portion of FIG. 6C illustrate voltages at the control node 15 and the virtual ground (VG) node depending on a state of the output signal SPKOUT. In the graph, V_{SS} represents a ground voltage.

As can be seen from the graphs of FIG. 6C, the voltage at the control node becomes a ground voltage V_{SS} when both the first output signal SPKOUT_N and the second output signal SPKOUT_P are at a high level, and becomes a driving voltage V_{DD} when both the first output signal SPKOUT_N and the second output signal SPKOUT_P are at a low level, but a compensation voltage corresponding to a level of the mean voltage VCM is not defined when one of the first output signal SPKOUT_N and the second output signal SPKOUT_P is at a high level and the other signal is at a low level.

In this case, the voltage at the VG node fluctuates at two levels as illustrated in Equations 5 and 6 below.

$${V}_{VG , HH ( LL )} = \frac{{R}_{I}}{{R}_{F} + 2 {R}_{I}} {V}_{DD} + \frac{{R}_{F}}{{R}_{F} + 2 {R}_{I}} {V}_{IN} , \qquad Equation 5$$

where V_{VG,HH}(LL) is a voltage at the VG node when both the first output signal SPKOUT_N and the second output signal SPKOUT_P are a high or low level, V_{DD} is a driving voltage used in the driver 130 of the audio amplifier 100, VIN is a DC level of an input signal, R_{I} is a resistance value of an input resistor, and RF is a resistance value of a feedback resistor.

$${V}_{VG , HL ( LH )} = \frac{{R}_{I}}{{R}_{F} + {R}_{I}} \frac{{V}_{DD}}{2} + \frac{{R}_{F}}{{R}_{F} + {R}_{I}} {V}_{IN} , \qquad Equation 6$$

where V_{VG,HL(LH)} is a voltage at the VG node when one of the first output signal SPKOUT_N and the second output signal SPKOUT_P is at a high level and the other signal is at a low level, V_{DD} is a driving voltage used in the driver 130 of the audio amplifier 100, VIN is a DC level of an input signal, Rr is a resistance value of an input resistor, and RF is a resistance value of a feedback resistor.

Referring to FIG. 6C and Equations 5 and 6, it can be seen that when the common mode compensation circuit 150 does not generate a compensation voltage corresponding to the level of the mean voltage VCM, the fluctuation in common mode voltage is eliminated only in the case in which the DC level of the input signal VIN is V_{DD}/2, and is not completely eliminated in the other cases.

In the case of various embodiments, as described above, a compensation voltage for each of a plurality of levels of a common mode voltage of an output signal pair is generated and provided to the loop filter 110, so that a fluctuation in the common mode voltage may be eliminated regardless of a DC level of the input signal. As a result, high versatility may be achieved.

For example, a high driving voltage of approximately 12 V may be used in an output terminal (for example, the driver 130) such that an audio amplifier, used in a mobile device or a wearable device, supports a power output of approximately 6 W. However, for various reasons, it is typically not recommended to use an input signal after a DC level thereof is increased to 6 V, and the input signal is not actually used in such a manner. Example embodiments provide a technique capable of eliminating a fluctuation in common mode voltage regardless of a DC level of an input signal.

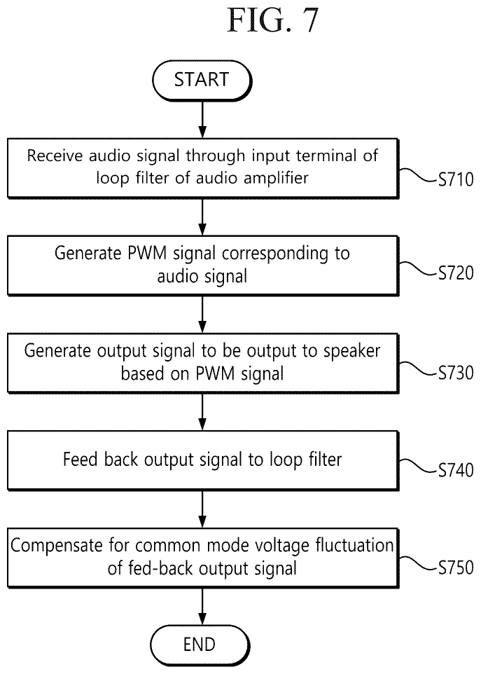

FIG. 7 is a flowchart illustrating a method of operating an audio amplifier according to an example embodiment.

Referring to FIG. 7, in operation S710, the audio amplifier 100 may receive an audio signal through the input terminals 1 and 2 of the loop filter 110 of the audio amplifier 100. In this case, the audio signal may be a differential signal.

In operation S720, the audio amplifier 100 may generate a PWM signal corresponding to the input audio signal. In operation S730, the audio amplifier 100 may generate an output signal to be output to the speaker 200, based on the PWM signal.

In operation S740, the audio amplifier 100 may feed back the output signal to the loop filter 110. As the output signal is fed back to the loop filter 110 as described above, a fluctuation in common mode voltage of the output signal may be input to the loop filter 110 to affect performance of the audio amplifier 100.

In operation S750, the audio amplifier 100 may compensate for the fluctuation in the common mode voltage of the fed-back output signal. For example, the audio amplifier 100 may generate a compensation voltage for each of a plurality of levels of the common mode voltage, and may provide the generated compensation voltage to the input terminals 1 and 2 of the loop filter 110 to compensate for the fluctuation in the common mode voltage input to the loop filter 110.

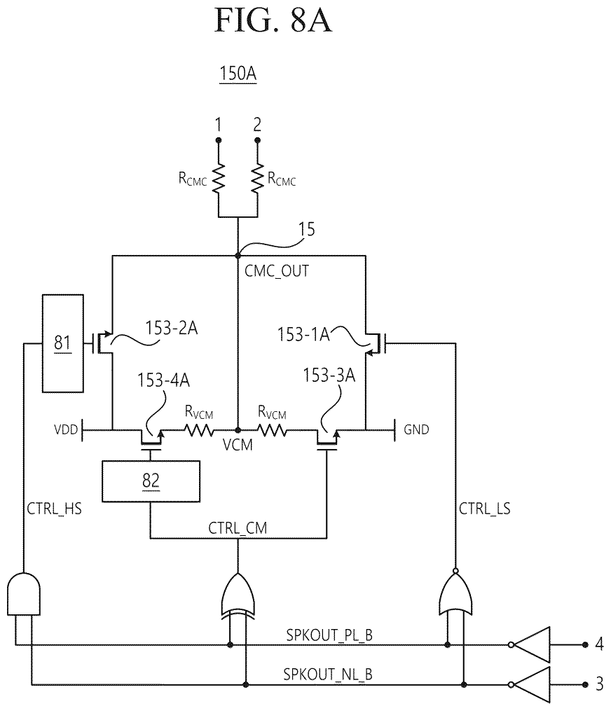

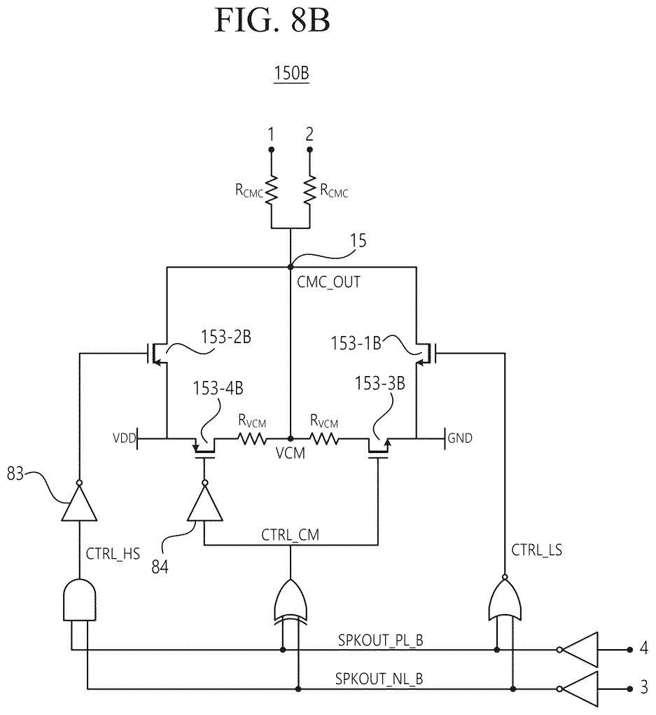

FIG. 8A is a diagram illustrating an example of implementing a common mode compensation circuit according to an example embodiment.

In general, ON-resistance of an n-type metal oxide semiconductor (NMOS) switch is lower than ON-resistance of a PMOS switch, and NMOS switches are more commonly employed in high-power amplifiers than p-type metal oxide semiconductor (PMOS) switches. Accordingly, according to an example embodiment, all of the first to fourth switches 153-1, 153-2, 153-3, and 153-4 of the common mode compensation circuit 150 may be implemented as NMOS switches.

Referring to FIG. 8A, it can be seen that each of the first switch 153-1A, the second switch 153-2A, the third switch 153-3A, and the fourth switch 153-4A of the common mode compensation circuit 150A is an NMOS switch. In this case, voltages of control signals applied to gate terminals of the second switch 153-2A and the fourth switch 153-4A may be bootstrapped to drive the second switch 153-2A and 153-4A connected to the driving voltage V_{DD}.

To this end, the common mode compensation circuit 150A may include a first bootstrap circuit 81 that bootstraps a second control signal CTRL_HS applied to the gate terminal of the second switch 153-2A, and a second bootstrap circuit 82 that bootstraps a third control signal CTRL_CM applied to the gate terminal of the fourth switch 153-4A, as illustrated in FIG. 8A.

The other components illustrated in FIG. 8A are the same as those of the common mode compensation circuit 150 illustrated in FIG. 4, and for convenience of explanation, redundant descriptions thereof will be omitted.

FIG. 8B is a diagram illustrating an example of implementing a common mode compensation circuit according to an example embodiment.

According to an example embodiment, among first to fourth switches 153-1B, 153-2B, 153-3B, and 153-4B of the common mode compensation circuit 150B, the second switch 153-2B and the fourth switch 153-4B connected to a driving voltage V_{DD} may be implemented as PMOS switches, and the first switch 153-1B and the third switch 153-3B connected to a ground voltage GND may be implemented as NMOS switches.

Referring to FIG. 8B, in an embodiment, each of the second switch 153-2B and the fourth switch 153-4B of the common mode compensation circuit 150B is a PMOS switch, and each of the first switch 153-1B and the third switch 153-3B is an NMOS switch. In this case, voltages of control signals applied to the gate terminals of the second switch 153-2B and the fourth switch 153-4B may be inverted to drive the second switch 153-2B and the fourth switch 153-4B connected to the driving voltage V_{DD}.

To this end, the common mode compensation circuit 150B may include a third inverter 83 that inverts the second control signal CTRL_HS applied to the gate terminal of the second switch 153-2B, and a fourth inverter 84 that inverts the third control signal CTRL_CM applied to the gate terminal of the fourth switch 153-4B, as illustrated in FIG. 8B.

The other components illustrated in FIG. 8B are the same as those of the common mode compensation circuit 150 illustrated in FIG. 4, and for convenience of explanation, redundant descriptions thereof will be omitted.

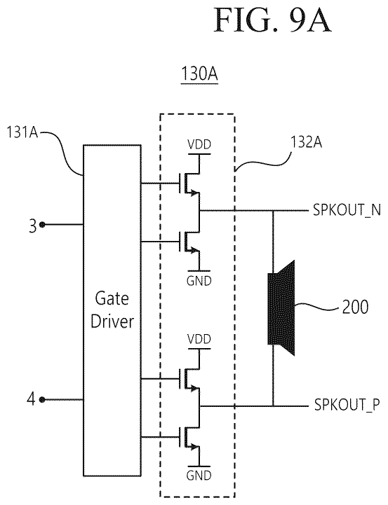

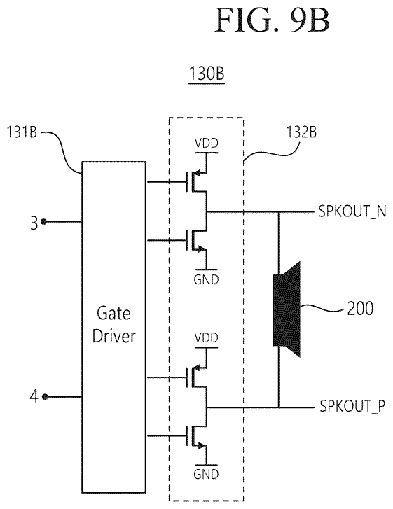

FIG. 9A is a diagram illustrating a configuration of a driver according to an example embodiment.

Referring to FIG. 9A, a driver 130A may include a gate driver 131A that generates drive signals based on PWM signals output from a PWM generator 120, a plurality of switches driven by the driving signals, and a power driver 132A that generates an output signal pair SPKOUT_N and SPKOUT_P. In this case, in an embodiment, the plurality of switches included in the power driver 132A are all implemented as NMOS switches to implement a high-power amplifier.

FIG. 9B is a diagram illustrating a configuration of a driver according to an embodiment.

Referring to FIG. 9B, a driver 130B may include a gate driver 131B that generates drive signals based on PWM signals output from a PWM generator 120, a plurality of switches driven by the driving signals, and a power driver 132B that generates an output signal pair SPKOUT_N and SPKOUT_P. In this case, unlike the example of FIG. 9A, among the plurality of switches included in the power driver 132B, switches connected to a driving voltage V_{DD} are implemented as PMOS switches, and switches connected to a ground voltage GND are implemented as NMOS switches.

In this case, according to an example embodiment, first to fourth switches 153-1, 153-2, 153-3, and 153-4 of a common mode compensation circuit 150 may have the same configuration as the switches of the power driver. For example, an audio amplifier including the power driver 132A illustrated in FIG. 9A may include a common mode compensation circuit 150A having the same configuration as illustrated in FIG. 8A. In addition, an audio amplifier including the power driver 132B illustrated in FIG. 9B may include a common mode compensation circuit 150B having the same configuration as illustrated in FIG. 8B. In this case, the design permits a configuration of a peripheral circuit of the power driver to be used together in a common mode compensation circuit.

However, example embodiments are not limited thereto. For example, according to an example embodiment, the common mode compensation circuit 150B having the same configuration as illustrated in FIG. 8B may be applied to an audio amplifier including the power driver 132A illustrated in FIG. 9A, and the common mode compensation circuit 150a having the same configuration as illustrated in FIG. 8A may be applied to an audio amplifier including the power driver 132B illustrated in FIG. 9B.

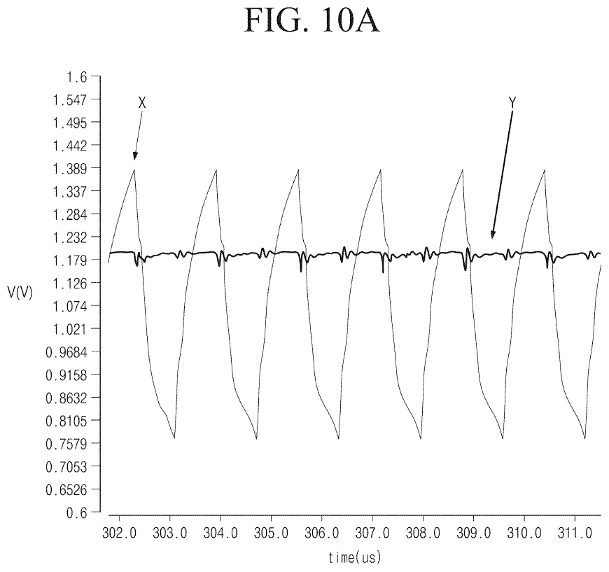

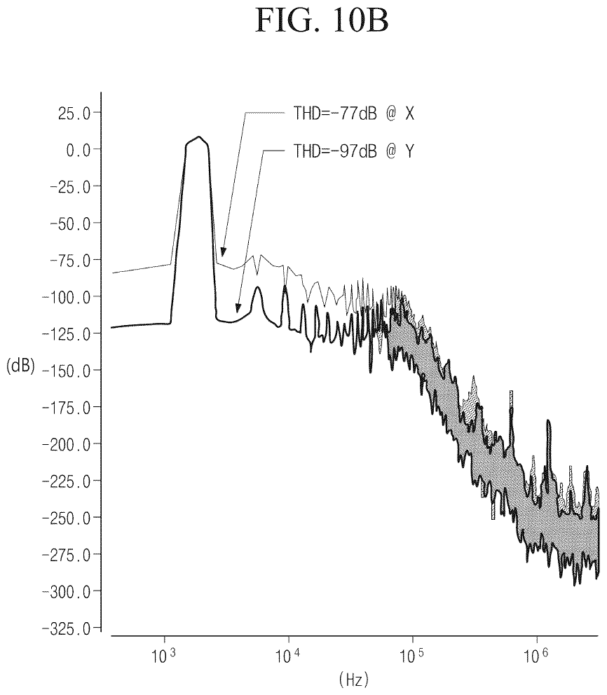

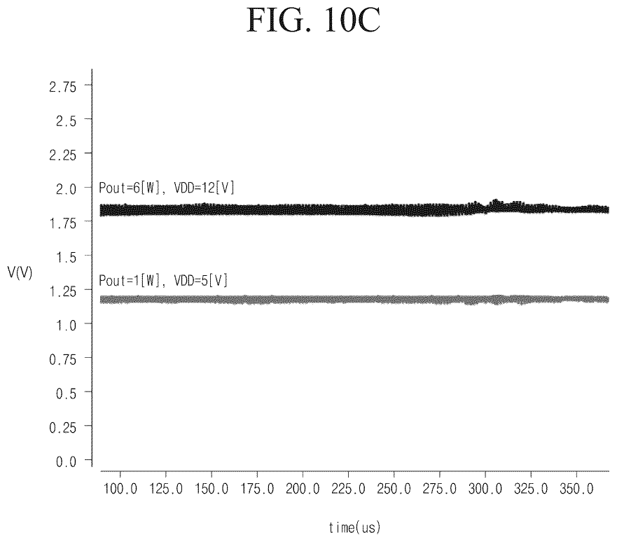

FIGS. 10A to 10C are diagrams illustrating simulated waveforms of the audio amplifier 100 according to various embodiments.

FIG. 10A illustrates a voltage at a virtual ground (VG) node of a first amplifier 111 of a loop filter 110 in an audio amplifier using a driving voltage of 5 V for an output of 1 W. In FIG. 10A, X represents a case in which a common mode compensation circuit 150 is not applied, and Y represents a case in which the common mode compensation circuit 150 is applied. From the drawing, it can be seen that when the common mode compensation circuit 150 is applied, a fluctuation in the voltage at the VG node is significantly reduced.

FIG. 10B illustrates total harmonic distortion (THD) in an audio amplifier using a driving voltage of 5 V for an output of 1 W. In FIG. 10B, X represents a case in which a common mode compensation circuit 150 is not applied, and Y represents a case in which the common mode compensation circuit 150 is applied. From the drawing, it can be seen that the THD is significantly reduced in the case in which the common mode compensation circuit 150 is applied.

FIG. 10C illustrates a fluctuation in voltage at a VG node in an audio amplifier using a driving voltage of 5 V for an output of 1 W and an audio amplifier using a driving voltage of 12 V for an output of 6 W. From the drawing, it can be seen that a fluctuation in common mode voltage input to the loop filter 110 may be significantly reduced under various output and power supply conditions.

The above-described audio amplifier 100 may be, for example, a class D audio amplifier with BD modulation, but example embodiments are not limited thereto.

According to the above-described various embodiments, an audio amplifier capable of compensating for a fluctuation in common mode voltage under various power supply conditions, and a method thereof, may be provided.

For example, referring to a comparative example in which an anti-phase signal of an output common mode voltage is generated using an inverting amplifier, a significantly high-speed operation is performed to respond to a PWM pulse, resulting in significant power consumption. In addition, a—1× gain of the inverting amplifier is not achieved, and complete compensation of a common mode voltage compensation is not performed. In addition, the inverting amplifier typically normally operates within a driving voltage range of 2.5 V to 12 V to respond to a high-power speaker, but design of such an inverting amplifier may be difficult according to a comparative example. In addition, referring to a comparative example, there are various methods of converting an analog signal to a PWM signal in a class D amplifier, and although a BD modulation method may eliminate the need for an output filter, a BD modulation method may cause a fluctuation in common mod voltage. Still referring to a comparative example, since a class D amplifier constitutes a closed loop circuit in which an output signal is fed back to an input terminal, a fluctuation in common mode voltage present in the output signal may be input to the input terminal, which may cause performance degradation. For example, as power at an output terminal stage is increased, the fluctuation in the common mode voltage is also increased. Therefore, performance of the class D amplifier according to a comparative example may be significantly deteriorated.

In contrast, according to various embodiments, compensation of an input common mode voltage may be performed using a switch and a logic gate without use of an operational amplifier. Therefore, an audio amplifier may be efficiently implemented, a high-speed response to a PWM pulse may be provided, and power consumption may be significantly low. In addition, due to use of an LDMOS switch, the audio amplifier may normally operate within an entire driving voltage range of about 2.5 V to about 12 V without occurrence of withstand issues.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

As set forth above, according to various embodiments, an audio amplifier capable of compensating for a fluctuation in common mode voltage under various power supply conditions and a method of operating the same may be provided.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. An audio amplifier, comprising:
a loop filter configured to receive a differential input signal pair;
a pulse-width modulation (PWM) signal generator configured to generate PWM signals, corresponding to the differential input signal pair, based on signals received from the loop filter;
a driver configured to generate an output signal pair based on the PWM signals;
a feedback circuit configured to feed back the output signal pair to the loop filter; and
a common mode compensation circuit configured to compensate for a fluctuation in a common mode voltage of the fed-back output signal pair,
wherein the common mode compensation circuit generates a compensation voltage for each of a plurality of levels of the common mode voltage, and provides the generated compensation voltage to the loop filter.

2. The audio amplifier of claim 1, wherein
the PWM signal generator is driven by a power supply voltage,
the driver is driven by a driving voltage higher than or equal to the power supply voltage, and
the common mode compensation circuit generates the compensation voltage based on the PWM signals.

3. The audio amplifier of claim 2, wherein
the PWM signal generator comprises:
a first comparator configured to generate a first PWM signal by comparing a triangle wave with a first output of the loop filter; and
a second comparator configured to generate a second PWM signal by comparing the triangle wave with a second output of the loop filter,
wherein the common mode compensation circuit generates the compensation voltage based on the first PWM signal and the second PWM signal.

4. The audio amplifier of claim 3, wherein
the common mode compensation circuit comprises a control node connected to a first input terminal and a second input terminal of the loop filter, and
the common mode compensation circuit is configured to:
apply a ground voltage to the control node when both a first output signal and a second output signal, included in the output signal pair, are at a high level;
apply the driving voltage to the control node when both the first and second output signals are at a low level; and
apply a mean voltage of the driving voltage and the ground voltage to the control node when one of the first and second output signals is at a high level and the other one of the first and second output signals is at a low level.

5. The audio amplifier of claim 4, wherein
the first and second input terminals are connected to an input terminal pair of a first amplifier included in the loop filter,
the feedback circuit comprises a first feedback resistor configured to feed back the first output signal to the first input terminal of the loop filter, and a second feedback resistor configured to feed back the second output signal to the second input terminal of the loop filter, and
the common mode compensation circuit comprises a first compensation resistor connected between the control node and the first input terminal of the loop filter, and a second compensation resistor connected between the control node and the second input terminal of the loop filter.

6. The audio amplifier of claim 5, wherein
a positive input signal, included in the differential input signal pair, is applied to the first input terminal of the loop filter through a first input resistor,
a negative input signal, included in the differential input signal pair, is applied to the second input terminal of the loop filter through a second input resistor,
the first output signal is a negative output signal included in the output signal pair, and
the second output signal is a positive signal included in the output signal pair.

7. The audio amplifier of claim 4, wherein
the common mode compensation circuit further comprises:
a first switch having one end connected to the ground voltage and another end connected to the control node;
a second switch having one end connected to the driving voltage and another end connected to the control node;
a third switch having one end connected to the ground voltage and another end connected to the control node through a first intermediate resistor; and
a fourth switch having one end connected to the driving voltage and another end connected to the control node through a second intermediate resistor.

8. The audio amplifier of claim 7, wherein
the common mode compensation circuit further comprises:
a first logic gate configured to generate a first control signal that controls turn-on and turn-off operations of the first switch;
a second logic gate configured to generate a second control signal that controls turn-on and turn-off operations of the second switch; and
a third logic gate configured to generate a third control signal that controls turn-on and turn-off operations of the third and fourth switches.

9. The audio amplifier of claim 8, wherein
the common mode compensation circuit further comprises a first inverter configured to generate a first inverted PWM signal by inverting the first PWM signal, and a second inverter configured to generate a second inverted PWM signal by inverting the second PWM signal,
the first logic gate is a NOR gate configured to generate the first control signal based on the first and second inverted PWM signals and to output the generated first control signal to a gate terminal of the first switch,
the second logic gate is an AND gate configured to generate the second control signal based on the first and second inverted PWM signals and to output the generated second control signal to a gate terminal of the second switch, and
the third logic gate is an XOR gate configured to generate the third control signal based on the first and second inverted PWM signals and to output the generated third control signal to a gate terminal of the third switch and a gate terminal of the fourth switch.

10. The audio amplifier of claim 9, wherein
each of the first to fourth switches is an n-type metal oxide semiconductor (NMOS) switch, and
the common mode compensation circuit further comprises:
a first bootstrap circuit configured to bootstrap the second control signal applied to the gate terminal of the second switch; and
a second bootstrap circuit configured to bootstrap the third control signal applied to the gate terminal of the fourth switch.

11. The audio amplifier of claim 9, wherein
each of the first and third switches is an n-type metal oxide semiconductor (NMOS) switch,
each of the second and fourth switches is a-type metal oxide semiconductor (PMOS) switch, and
the common mode compensation circuit further comprises:
a third inverter configured to invert the second control signal applied to the gate terminal of the second switch; and
a fourth inverter configured to invert the third control signal applied to the gate terminal of the fourth switch.

12. The audio amplifier of claim 4, wherein
a value of a DC level of the differential input signal pair and a value of the mean voltage are different.

13. The audio amplifier of claim 5, wherein
the first feedback resistor, the second feedback resistor, the first compensation resistor, and the second compensation resistor have a same resistance value.

14. The audio amplifier of claim 7, wherein
each of the first to fourth switches is a lateral double-diffused MOS (LDMOS) switch.

15. The audio amplifier of claim 7, wherein
the driver comprises:
a gate driver configured to generate driving signals based on the PWM signals; and
a power driver comprising a plurality of switches driven by the driving signal and configured to generate the output signal pair.

16. The audio amplifier of claim 15, wherein
each of the plurality of switches of the power driver and the first to fourth switches is an n-type metal oxide semiconductor (NMOS) switch.

17. The audio amplifier of claim 15, wherein
the plurality of switches of the power driver comprises a p-type metal oxide semiconductor (PMOS) switch connected to the driving voltage, and an n-type metal oxide semiconductor (NMOS) switch connected to the ground voltage,
each of the first and third switches is an NMOS switch, and
each of the second and fourth switches is a PMOS switch.

18. The audio amplifier of claim 1, wherein
the audio amplifier is a class D amplifier with DB modulation.

19. A method of operating an audio amplifier, the method comprising:
receiving an audio signal through an input terminal of a loop filter of the audio amplifier;
generating a pulse-width modulation (PWM) signal corresponding to the audio signal;
generating an output signal to be output to a speaker, based on the PWM signal;
feeding back the output signal to the loop filter; and
compensating for a fluctuation in a common mode voltage of the fed-back output signal,
wherein
compensating for the fluctuation comprises:
generating a compensation voltage for each of a plurality of levels of the common mode voltage; and
providing the generated compensation voltage to the loop filter.

20. A class D audio amplifier with BD modulation, the class D audio amplifier comprising:
a loop filter;
a pulse-width modulation (PWM) signal generator;
a gate driver;
a power driver;
a feedback circuit; and
a common mode compensation circuit,
wherein
the common mode compensation circuit comprises a control node connected to a first input terminal and a second input terminal of the loop filter, and
the common mode compensation circuit is configured to:
apply a ground voltage to the control node when both a first output signal and a second output signal of the class D audio amplifier are at a high level;
apply a driving voltage to the control node when both the first output signal and the second output signal are at a low level; and
apply a mean voltage of the driving voltage and the ground voltage to the control node when one of the first and second output signals is at a high level and the other one of the first and second output signals is at a low level.
